(19) United States
(12) Patent Application Publication
(10) Pub. No.: US 2016/0351841 A1
(43) Pub. Date: Dec. 1, 2016

(54) SOLAR CELL INCLUDING LIGHT ABSORBER CONTAINING PEROVSKITE COMPOUND, AND SOLAR CELL MODULE

(71) Applicant: Panasonic Corporation, Osaka (JP)

(72) Inventor: MICHIO SUZUKA, Osaka (JP)

(21) Appl. No.: 15/157,474

(22) Filed: May 18, 2016

(30) Foreign Application Priority Data
May 25, 2015 (JP) 2015-105068

(51) Int. Cl. H01L 51/42; H01L 27/30

(52) U.S. Cl. CPC H01L 51/4206; H01L 27/301; H01L 51/4253

(57) ABSTRACT

A solar cell according to an aspect of the present disclosure includes; a substrate; a first collector on the principal surface of the substrate; a dielectric covering a portion of the principal surface and a first portion of the first collector; a light absorber covering at least a second portion of the first collector and a portion of the dielectric and containing a perovskite compound; and a second collector on the light absorber and the dielectric. The difference between the height, from the principal surface, of the top of the dielectric in the region where it covers the first portion of the first collector and the height, from the principal surface, of the bottom of the light absorber in the region where it covers the at least the second portion of the first collector and does not cover the dielectric is 200 nm or less.

### BACKGROUND

### 1. Technical Field

The present disclosure relates to solar cells.

### 2. Description of the Related Art

In recent years, perovskite solar cells, which use a perovskite crystal, represented by a compositional formula of ABX₃, or a similar structure as a light-absorbing material, have been under research and development.

Jeong-Hyeok Im et al., “Nature Nanotechnology” (US) Vol. 9, pp. 927-932, November 2014 discloses perovskite solar cells that use a CH₃NH₃PbI₃ perovskite layer as a light absorber.

### SUMMARY

In one general aspect, the techniques disclosed here feature a solar cell. The solar cell includes a substrate, a first collector, a dielectric, a light absorber, and a second collector. The substrate has a principal surface, and the first collector is on the principal surface. The dielectric covers a portion of the principal surface and a first portion of the first collector. The light absorber covers at least a second portion of the first collector and a portion of the dielectric and contains a perovskite compound represented by a compositional formula of ABX₃ (where A is a site for one or more monovalent cations, B is a site for one or more divalent cations, and X is a site for one or more halide anions). The second collector is on the light absorber and the dielectric and is insulated from the first collector by the dielectric. In a cross-section perpendicular to the principal surface, the difference between the height, from the principal surface, of the top of the dielectric in the region where it covers the first portion of the first collector and the height, from the principal surface, of the bottom of the light absorber in the region where it covers the at least the second portion of the first collector and does not cover the dielectric is 200 nm or less.

An embodiment of the present disclosure makes leakage current in solar cells less likely, thereby reducing the associated decreases in the conversion efficiency of the solar cells.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a cross-sectional view of a solar cell according to a first embodiment of the present disclosure;

FIG. 1B is a cross-sectional view of a solar cell according to a variation of the first embodiment of the present disclosure;

FIG. 2 is a cross-sectional view of a solar cell according to a first comparative embodiment;

FIG. 3 is a cross-sectional view of a solar cell of a second comparative embodiment;

FIG. 4 is a cross-sectional view of a solar cell according to a second embodiment of the present disclosure;

FIG. 5 is a cross-sectional view of a solar cell according to a third embodiment of the present disclosure;

FIG. 6 is a cross-sectional view of a solar cell according to a fourth embodiment of the present disclosure;

FIG. 7 is a cross-sectional view of a solar cell module according to a fifth embodiment of the present disclosure;

FIG. 8 is a cross-sectional view of a solar cell of Example 1 of the present disclosure; and

FIG. 9 is a plan view of the substrate of the solar cell illustrated in FIG. 8.

### DETAILED DESCRIPTION

The present disclosure includes solar cells and solar cell modules described under the following items.

### Item 1

A solar cell comprising:
a substrate having a principal surface;
a first collector on the principal surface;
a dielectric covering a portion of the principal surface and a first portion of the first collector;
a light absorber covering at least a second portion of the first collector and a portion of the dielectric and containing a perovskite compound represented by a compositional formula of ABX₃, where A is a site for one or more monovalent cations, B is a site for one or more divalent cations, and X is a site for one or more halide anions; and
a second collector on the light absorber and the dielectric, the second collector insulated from the first collector by the dielectric, wherein
in a cross-section perpendicular to the principal surface,
a difference between a height, from the principal surface, of a top of the dielectric in a region where the dielectric covers the first portion of the first collector and
a height, from the principal surface, of a bottom of the light absorber in a region where the light absorber covers the at least the second portion of the first collector and does not cover the dielectric is 200 nm or less.

In the solar cell according to item 1, the difference between the height, from the principal surface, of the top of the dielectric in the region where the dielectric covers the first portion of the first collector and the height, from the principal surface, of the bottom of the light absorber in the region where the light absorber covers the at least the second portion of the first collector and does not cover the dielectric may be 160 nm or less.

### Item 2

The solar cell according to item 1, further comprising an electron transport layer between the first collector and the light absorber, the electron transport layer containing a semiconductor, wherein

the dielectric covers a portion of the electron transport layer.

### Item 3

The solar cell according to item 2, further comprising a porous layer in the light absorber, the porous layer positioned in contact with the electron transport layer and including a porous medium.

### Item 4

The solar cell according to any of items 1 to 3, further comprising a hole transport layer between the light absorber and the second collector.

### Item 5

The solar cell according to item 2, wherein the semiconductor is titanium oxide.

### Item 6

The solar cell according to any of items 1 to 5, wherein the second collector contains carbon.

### Item 7

The solar cell according to any of items 1 to 6, wherein the one or more monovalent cations include at least one selected from the group consisting of a methylammonium cation and a formamidinium cation.

### Item 8

The solar cell according to any of items 1 to 7, wherein the one or more divalent cations include at least one selected from the group consisting of Pb²⁺, Ge²⁺, and Sn²⁺.

### Item 9

A solar cell comprising:
a substrate having a principal surface;
a first collector on the principal surface;
a dielectric covering a portion of the principal surface and a first portion of the first collector;
a light absorber covering at least a second portion of the first collector and a portion of the dielectric and containing a perovskite compound represented by a compositional formula of ABX₃, where A is a site for one or more monovalent cations, B is a site for one or more divalent cations, and X is a site for one or more halide anions; and
a second collector on the light absorber and the dielectric, the second collector insulated from the first collector by the dielectric, wherein
in a cross-section perpendicular to the principal surface,
a ratio of a difference between a height, from the principal surface, of a top of the dielectric in a region where the dielectric covers the first portion of the first collector and
a height, from the principal surface, of a bottom of the light absorber in a region where the light absorber covers the at least the second portion of the first collector and does not cover the dielectric to a thickness of the light absorber is 0.67 or less.

### Item 10

A solar cell module comprising:
a first solar cell including:
a substrate having a principal surface;
a first collector on the principal surface;
a first dielectric covering a first portion of the principal surface and a first portion of the first collector;
a first light absorber covering at least a second portion of the first collector and a portion of the first dielectric and containing a perovskite compound represented by a compositional formula of ABX₃, where A is a site for one or more monovalent cations, B is a site for one or more divalent cations, and X is a site for one or more halide anions; and
a second collector on the first light absorber and the first dielectric, the second collector insulated from the first collector by the first dielectric, wherein
in a cross-section perpendicular to the principal surface,
a difference between a height, from the principal surface, of a top of the first dielectric in a region where the first dielectric covers the first portion of the first collector and
a height, from the principal surface, of a bottom of the first light absorber in a region where the first light absorber covers the at least the second portion of the first collector and does not cover the first dielectric is 200 nm or less; and
a second solar cell including:
a third collector on the principal surface, the third collector adjacent to the first collector;
a second dielectric covering a second portion of the principal surface and a first portion of the third collector;
a second light absorber covering at least a second portion of the third collector and a portion of the second dielectric and containing the perovskite compound; and
a fourth collector on the second light absorber and the second dielectric, the fourth collector insulated from the third collector by the second dielectric, wherein
in a cross-section perpendicular to the principal surface,
a difference between a height, from the principal surface, of a top of the second dielectric in a region where the second dielectric covers the first portion of the third collector and
a height, from the principal surface, of a bottom of the second light absorber in a region where the second light absorber covers the at least the second portion of the third collector and does not cover the second dielectric is 200 nm or less, wherein
the second collector is in contact with a portion of the third collector.

In the solar cell module according to item 10, the difference between the height, from the principal surface, of the top of the first dielectric in the region where the first dielectric covers the first portion of the first collector and the height, from the principal surface, of the bottom of the first light absorber in the region where the first light absorber covers the at least the second portion of the first collector and does not cover the first dielectric may be 160 nm or less.

In the solar cell module according to item 10, furthermore, the difference between the height, from the principal surface, of the top of the second dielectric in the region where the second dielectric covers the first portion of the third collector and the height, from the principal surface, of the bottom of the second light absorber in the region where the second light absorber covers the at least the second portion of the third collector and does not cover the second dielectric may be 160 nm or less.

The following describes some embodiments of the present disclosure with reference to drawings.

### First Embodiment

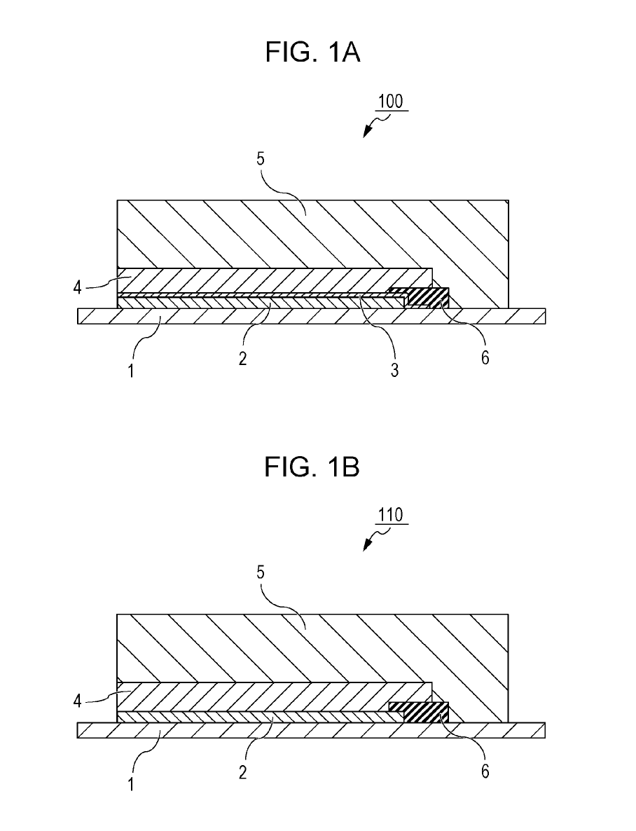

A solar cell 100 according to this embodiment has, as illustrated in FIG. 1A, a substrate 1, a first collector 2, an electron transport layer 3, a dielectric 6, a light absorber 4, and a second collector 5.

The first collector 2 is on a principal surface of the substrate 1. The electron transport layer 3 is on the first collector 2 and contains a semiconductor. The dielectric 6 covers a portion of the principal surface of the substrate 1, a first portion of the first collector 2, and a portion of the electron transport layer 3. The light absorber 4 is on the electron transport layer 3 and a portion of the dielectric 6 and contains a perovskite compound represented by a compositional formula of ABX₃. In this formula, A is a site for one or more monovalent cations, B is a site for one or more divalent cations, and X is a site for one or more halide anions. The second collector 5 is on the light absorber 4 and the dielectric 6 and is insulated from the first collector 2 and the electron transport layer 3 by the light absorber 4 and the dielectric 6. In a cross-section perpendicular to the principal surface of the substrate 1, the difference between the height, from the principal surface of the substrate 1, of the top of the dielectric 6 in the region where it covers the first portion of the first collector 2 and the height, from the principal surface of the substrate 1, of the bottom of the light absorber 4 in the region where it covers at least a second portion of the first collector 2 and does not cover the dielectric 6 is 200 nm or less. In other words, in a cross-section perpendicular to the principal surface of the substrate 1, the difference between the height, from the principal surface of the substrate 1, of the top of the dielectric 6 in the region where it is on the portion of the electron transport layer 3 and the combined thickness of the first collector 2 and the electron transport layer 3 is 200 nm or less.

The following describes the key operations and advantages of the solar cell 100 according to this embodiment.

When the solar cell 100 is illuminated with light, the light absorber 4 absorbs the light, generating electrons in the excited state and holes. The excited electrons move to the electron transport layer 3. The holes, generated in the light absorber 4, move to the second collector 5. Since the electron transport layer 3 is coupled to the first collector 2, the user can take electric current out of the solar cell 100 using the first collector 2 and the second collector 5 as an anode and a cathode, respectively.

In the solar cell 100, the dielectric 6 insulates the second collector 5 from the first collector 2 and the electron transport layer 3. This inhibits the movement of electrons from the electron transport layer 3 to the second collector 5, thereby preventing the recombination of electrons and holes at the interface between the electron transport layer 3 and the second collector 5. Leakage current becomes less likely, making the electrons and holes generated in the light absorber 4 highly available to be taken out in the form of current.

In a cross-section perpendicular to the principal surface of the substrate 1, as stated, the difference between the height, from the principal surface of the substrate 1, of the top of the dielectric 6 in the region where it covers the first portion of the first collector 2 and the height, from the principal surface of the substrate 1, of the bottom of the light absorber 4 in the region where it covers the at least the second portion of the first collector 2 and does not cover the dielectric 6 is 200 nm or less, and this ensures that the height gap between the dielectric 6 and the electron transport layer 3 is small and, therefore, that the light absorber 4 is flat. In other words, in a cross-section perpendicular to the principal surface of the substrate 1, the difference between the height, from the principal surface of the substrate 1, of the top of the dielectric 6 in the region where it is on the portion of the electron transport layer 3 and the combined thickness of the first collector 2 and the electron transport layer 3 is 200 nm or less, and this ensures a small height gap between the dielectric 6 and the electron transport layer 3 and therefore flatness of the light absorber 4. Defects and pinholes in the light absorber 4 are therefore rare events, and it is unlikely that the electron transport layer 3 and the second collector 5 come into contact via defects or pinholes. As a result, the leakage current associated with electrons flowing into the second collector 5 is reduced.

The light absorber 4 is partially on the dielectric 6, and this prevents the second collector 5 from intervening between the dielectric 6 and the light absorber 4. This makes leakage current due to contact between the second collector 5 and the electron transport layer 3 less likely.

The light absorber 4, furthermore, does not cover the entire dielectric 6. The dielectric 6 is therefore partially in contact with the second collector 5. This configuration ensures that the light absorber 4 is within the edge of the dielectric 6; therefore, the solar cell pitch is not increased.

The following describes how the position of the light absorber 4 influences its effect, referring to solar cells 101 and 102 as comparative embodiments.

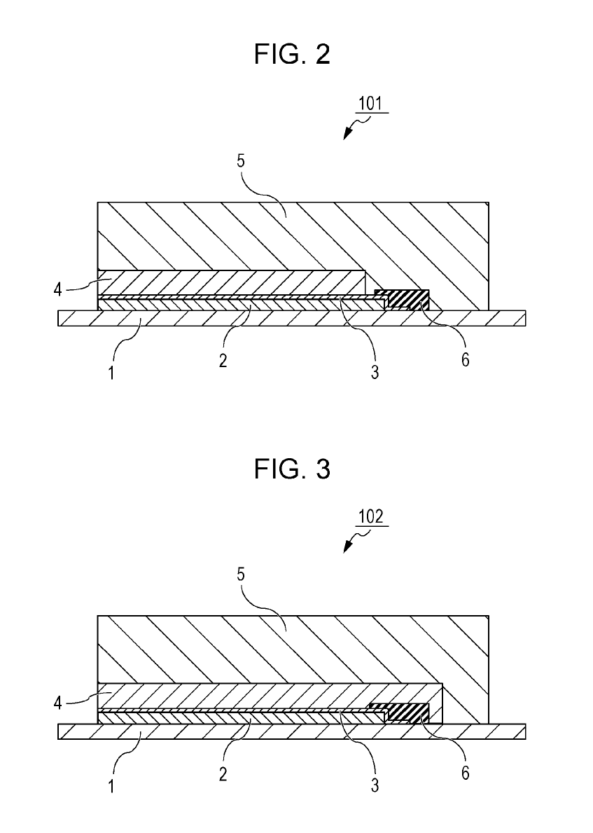

FIGS. 2 and 3 are schematics illustrating the structures of a solar cell 101 (a first comparative embodiment) and a solar cell 102 (a second comparative embodiment), respectively.

Failure to cover the dielectric 6 with the light absorber 4, leaving a gap between the light absorber 4 and the dielectric 6, as illustrated in FIG. 2 can lead to the intrusion of the second collector 5 into the gap. In such a case, leakage current occurs because of the contact between the second collector 5 and the electron transport layer 3.

Covering the entire dielectric 6 with the light absorber 4 as illustrated in FIG. 3 means allowing the light absorber 4 to extend beyond the edge of the dielectric 6. This leads to an increased solar cell pitch, which presents an obstacle in reducing the size of solar cell modules.

A configuration where the light absorber 4 is partially on the dielectric 6 and does not cover the entire dielectric 6 therefore allows the dielectric 6 to reduce leakage current as expected while allowing for the possibility of a reduced size of the solar cell 100.

The electron transport layer 3 may cover the side of the first collector 2 completely. This prevents the first collector 2 from coming into contact with the light absorber 4, thus limiting the movement of holes generated in the light absorber 4 into the first collector 2 and, therefore, the subsequent recombination with electrons.

The following is an example of a method for producing the solar cell 100 according to this embodiment. First, a first collector 2 is formed on the surface of a substrate 1. An electron transport layer 3 is formed on the first collector 2 using sputtering or any other technique. The electron transport layer 3 may be formed such that it is partially beyond the edge of the first collector 2 and reaches the substrate 1 as illustrated in FIG. 1A. A dielectric 6 is then formed on the substrate 1 and the electron transport layer 3 using coating or any other technique. A light absorber 4 is formed on the electron transport layer 3 and a portion of the dielectric 6 using coating or any other technique. A second collector 5 is formed on the light absorber 4 and the dielectric 6. Through this process, the solar cell 100 is obtained.

The following provides further details of the individual components of the solar cell 100.

### Substrate 1

The substrate 1 is a film that physically supports the individual layers of the solar cell 100 during the construction of the solar cell. The substrate 1 is permeable to light and can be, for example, a glass or plastic substrate (or plastic film).

### First Collector 2

The first collector 2 is conductive and permeable to light. The first collector 2 allows, for example, visible and near-infrared light to pass through.

The first collector 2 can be formed of a material such as a transparent and conductive metal oxide. Examples of transparent conductive metal oxides include indium tin oxide, antimony-doped tin oxide, fluorine-doped tin oxide, boron-, aluminum-, gallium-, or indium-doped zinc oxide, and composites thereof.

Alternatively, the first collector 2 may be a non-transparent material made into a pattern through which light can pass through. Examples of patterns that allow light to pass through include stripes, corrugations, mesh, and punched metal, which means a regular or irregular arrangement of a number of small through-holes, and also include reversal patterns, in which the empty areas in the original pattern are solid and vice versa. A first collector 2 having any of these patterns allows light to pass through the areas of the pattern where the electrode material does not exist. Examples of non-transparent electrode materials include platinum, gold, silver, copper, aluminum, rhodium, indium, titanium, iron, nickel, tin, zinc, and alloys containing any of these. Conductive carbon materials can also be used.

The optical transmittance of the first collector 2 is, for example, 50% or more and can be 80% or more. The wavelengths of light allowed to pass through are determined by the wavelengths that the light absorber 4 absorbs. The thickness of the first collector 2 is, for example, 1 nm or more and 1000 nm or less.

The use of a first collector 2 able to block holes coming from the light absorber 4 eliminates the need for the electron transport layer 3 in the solar cell as illustrated in FIG. 1B. FIG. 1B is a cross-sectional view of a solar cell 110 according to a variation of this embodiment. The ability to block holes coming from the light absorber 4 is defined as the quality of a material that allows electrons generated in the light absorber 4 to pass through but does not allow holes to pass through. Materials having such a quality possess a Fermi level more negative than the lowest energy level in the valence band of the light absorber 4. A specific example is aluminum.

### Light Absorber 4

The light absorber 4 contains an absorbing material that is a perovskite-structured compound, which is represented by a compositional formula of ABX₃. A is a site for monovalent cations. Examples of cations in A include monovalent cations such as alkali metal cations and organic cations. More specific examples include the methylammonium cation (CH₃NH₃⁺), the formamidinium cation (NH₂CHNH₂⁺), and the cesium cation (Cs⁺). B is a site for divalent cations. Examples of cations in B include divalent cations of the transition metals or the elements in groups 13 to 15. More specific examples include Pb²⁺, Ge²⁺, and Sn²⁺. X is a site for monovalent anions, such as halide anions. There may be two or more kinds of ions in each of the sites A, B, and X. Specific examples of suitable perovskite-structured compounds include CH₃NH₃PbI₃, NH₂CHNH₂PbI₃, CH₃NH₃PbBr₃, CH₃NH₃PbCl₃, CsPbI₃, and CsPbBr₃.

The thickness of the light absorber 4 is, for example, in the range of 100 nm to 1000 nm, although varying according to the absorption capacity of the layer. The light absorber 4 can be formed using techniques such as the application of a solution and co-deposition of materials.

The light absorber 4 may have a portion where it contains the material for the electron transport layer 3.

### Electron Transport Layer 3

The electron transport layer 3 contains a semiconductor and can be a semiconductor having a band gap of 3.0 eV or more. When the electron transport layer 3 is formed of a material having a band gap of 3.0 eV or more, visible and infrared light is allowed to reach the light absorber 4. The semiconductor can be, for example, an organic or inorganic n-type semiconductor.

Examples of organic n-type semiconductors include imide compounds, quinone compounds, and fullerene and its derivatives. Examples of inorganic semiconductors that can be used include metal oxides and perovskite oxides. Examples of suitable metal oxides include oxides of Cd, Zn, In, Pb, Mo, W, Sb, Bi, Cu, Hg, Ti, Ag, Mn, Fe, V, Sn, Zr, Sr, Ga, and Cr. A more specific example is TiO₂. Examples of suitable perovskite oxides include SrTiO₃ and CaTiO₃.

Alternatively, the electron transport layer 3 may be formed of a substance having a band gap of more than 6 eV. Examples of substances having a band gap of more than 6 eV include alkali metal or alkaline earth metal halides such as lithium fluoride and calcium fluoride, alkali metal oxides such as magnesium oxide, and silicon dioxide. When any such substance is used, the electron transport layer 3 is formed to a thickness of roughly 10 nm or less so that it is able to transport electrons.

The electron transport layer 3 can be a stack of layers of different materials and can also be a stack of alternating layers of two materials.

### Dielectric 6

The dielectric 6 can be made of any insulating material, including resin materials, inorganic oxides, inorganic nitrides, and high-band-gap semiconductors. Specific examples of resin materials that can be used include polymers such as polystyrene, polyimide, polymethyl methacrylate, polyethylene, polypropylene, and butadiene rubber and their derivatives. Specific examples of suitable inorganic oxides and nitrides include oxides and nitrides of the alkali metals, the alkaline earth metals, the transition metals, and the elements in groups 13 and 14. These materials can be used alone or in mixture.

### Second Collector 5

The second collector 5 is able to block electrons coming from the light absorber 4. The ability to block electrons coming from the light absorber 4 is defined as the quality of a material that allows holes generated in the light absorber 4 to pass through but does not electrons. Materials having such a quality possess a Fermi level more positive than the highest energy level in the valence band of the light absorber 4. Specific examples include gold and carbon materials such as graphene.

### Second Embodiment

A solar cell 200 according to this embodiment differs from the solar cell 100 according to the first embodiment in that it has a porous layer 7.

The following describes the solar cell 200. Any component equivalent in terms of function and configuration to one described in the context of the solar cell 100 is referenced by the same numeral as for the solar cell 100 without repeating the description.

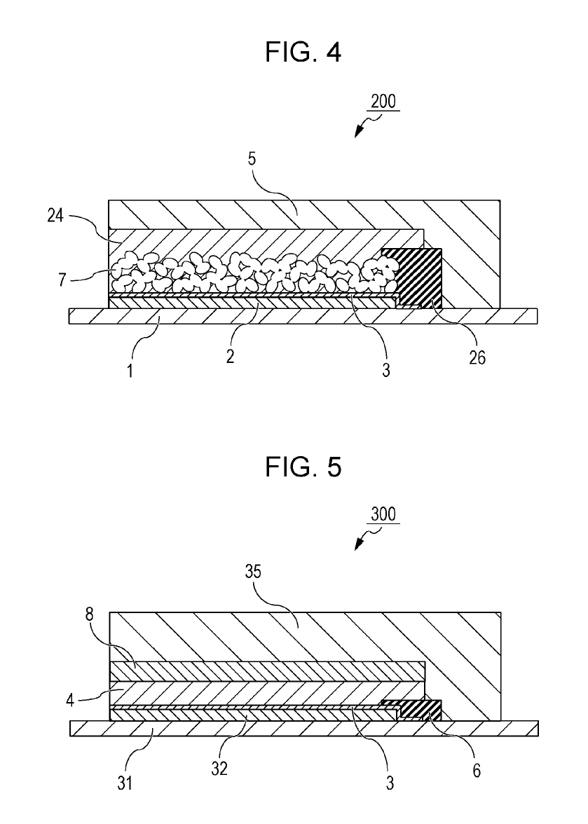

The solar cell 200 according to this embodiment has, as illustrated in FIG. 4, a substrate 1, a first collector 2, an electron transport layer 3, a porous layer 7, a dielectric 26, a light absorber 24, and a second collector 5.

The light absorber 24 is on the electron transport layer 3 and the dielectric 26. The second collector 5 is insulated from the first collector 2 and the electron transport layer 3 by the dielectric 26. The porous layer 7 is in the light absorber 24 and is positioned in contact with the electron transport layer 3. The dielectric 26 is on the substrate 1 and touches at least the side of the electron transport layer 3 and the side of the porous layer 7.

In a cross-section perpendicular to the principal surface of the substrate 1, the difference between the height, from the principal surface of the substrate 1, of the top of the dielectric 26 in the region where it covers a first portion of the first collector 2 and the height, from the principal surface of the substrate 1, of the bottom of the light absorber 24 in the region where it covers at least a second portion of the first collector 2 and does not cover the dielectric 26 is 200 nm or less. In other words, in a cross-section perpendicular to the principal surface of the substrate 1, the difference between the height, from the principal surface of the substrate 1, of the top of the dielectric 26 in the region where it is on a portion of the electron transport layer 3 and the combined thickness of the first collector 2 and the electron transport layer 3 is 200 nm or less. The thickness of the porous layer 7 is the difference between the mean y value of the curves constituting the top of the porous layer 7, assuming that the x and y axes are in the horizontal and vertical directions, respectively, in a cross-section taken in the vertical direction of the solar cell 200, and the height of the top of the electron transport layer 3.

The following describes the key operations and advantages of the solar cell 200 according to this embodiment.

The solar cell 200 operates in a similar way to the solar cell 100. The advantages this embodiment offers are similar to those of the first embodiment.

In addition to this, the porous layer 7 on the electron transport layer 3 allows the material for the light absorber 24 to penetrate into the pores thereof. The cavities in the porous layer 7 are therefore filled with the material for the light absorber 24. This increases the surface area of the light absorber 24, allowing more light to be absorbed within the light absorber 24.

In a cross-section perpendicular to the principal surface of the substrate 1, as stated, the difference between the height, from the principal surface of the substrate 1, of the top of the dielectric 26 in the region where it covers a first portion of the first collector 2 and the height, from the principal surface of the substrate 1, of the bottom of the light absorber 24 in the region where it covers at least a second portion of the first collector 2 and does not cover the dielectric 26 is 200 nm or less, and this ensures that the light absorber 24 is flat. In other words, in a cross-section perpendicular to the principal surface of the substrate 1, the difference between the height, from the principal surface of the substrate 1, of the top of the dielectric 26 in the region where it is on a portion of the electron transport layer 3 and the combined thickness of the first collector 2 and the electron transport layer 3 is 200 nm or less, and this ensures flatness of the light absorber 24. Defects and pinholes in the light absorber 24 are therefore rare events, and it is unlikely that the electron transport layer 3 and the second collector 5 come into contact via defects or pinholes. As a result, the leakage current associated with electrons flowing into the second collector 5 is reduced.

The fabrication of the solar cell 200 according to this embodiment is similar to that of the solar cell 100. The porous layer 7 is formed on the electron transport layer 3 using coating or any other technique.

The following provides further details of the individual components of the solar cell 200, excluding those the solar cell 100 also has.

### Porous Layer 7

The porous layer 7 is a base on which to form the light absorber 24 and does not inhibit the absorption of light by the light absorber 24 or the movement of electrons from the light absorber 24 to the electron transport layer 3.

The porous layer 7 includes a porous medium. The porous medium can be, for example, chains of insulating or semiconducting particles. The insulating particles can be particles of a material such as aluminum oxide or silicon oxide. The semiconducting particles can be particles of an inorganic semiconductor. Examples of inorganic semiconductors that can be used include metal oxides, perovskite oxides, sulfides, and metal chalcogenides. Examples of suitable metal oxides include oxides of Cd, Zn, In, Pb, Mo, W, Sb, Bi, Cu, Hg, Ti, Ag, Mn, Fe, V, Sn, Zr, Sr, Ga, and Cr. A more specific example is TiO₂. Examples of suitable perovskite oxides include SrTiO₃ and CaTiO₃. Examples of suitable sulfides include CdS, ZnS, In₂S₃, PbS, Mo₂S, WS₂, Sb₂S₃, Bi₂S₃, ZnCdS₂, and Cu₂S. Examples of suitable metal chalcogenides include CdSe, In₂Se₃, WSe₂, HgS, PbSe, and CdTe.

The thickness of the porous layer 7 can be 0.01 μm or more and 10 μm or less and can be 0.1 μm or more and 1 μm or less. The surface of the porous layer 7 may be rough. More specifically, the surface roughness factor, given as a fraction of the effective area to the projected area, can be 10 or more and can be 100 or more. The projected area of an object is the area of the shadow that appears behind the object when frontal lighting shines on the object. The effective area of an object is the actual surface area of the object and can be calculated from the volume of the object and the specific surface area and bulk density of the material of which the object is made. The volume of the object is determined from the projected area and thickness of the object.

### Light Absorber 24

The light absorber 24 can be configured in a similar way to the light absorber 4 according to the first embodiment.

### Dielectric 26

The dielectric 26 can be configured in a similar way to the dielectric 6 according to the first embodiment.

### Third Embodiment

A solar cell 300 according to this embodiment differs from the solar cell 100 according to the first embodiment in that it has a hole transport layer 8. In addition to this, the substrate 31, the first collector 32, and the second collector 35 of the solar cell 300 are configured differently from the corresponding components of the solar cell 100.

The following describes the solar cell 300. Any component equivalent in terms of function and configuration to one described in the context of the solar cell 100 is referenced by the same numeral as for the solar cell 100 without repeating the description.

The solar cell 300 according to this embodiment has, as illustrated in FIG. 5, a substrate 31, a first collector 32, an electron transport layer 3, a dielectric 6, a light absorber 4, a hole transport layer 8, and a second collector 35.

The hole transport layer 8 is provided between the light absorber 4 and the second collector 35.

The following describes the key operations and advantages of the solar cell 300 according to this embodiment.

When the solar cell 300 is illuminated with light, the light absorber 4 absorbs the light, generating electrons in the excited state and holes. The excited electrons move to the electron transport layer 3. The holes, generated in the light absorber 4, move to the hole transport layer 8. Since the electron transport layer 3 is coupled to the first collector 32 and the hole transport layer 8 is coupled to the second collector 35, the user can take electric current out of the solar cell 300 using the first collector 32 and the second collector 35 as an anode and a cathode, respectively.

The advantages this embodiment offers are similar to those of the first embodiment.

In this embodiment, furthermore, the presence of the hole transport layer 8 eliminates the need for the second collector 35 to have the ability to block electrons coming from the light absorber 4. This broadens the range of materials of which the second collector 35 can be made.

The fabrication of the solar cell 300 according to this embodiment is similar to that of the solar cell 100. The hole transport layer 8 is formed on the light absorber 4 using coating or any other technique.

The following provides further details of the individual components of the solar cell 300.

### First Collector 32 and Second Collector 35

In this embodiment, because of the presence of the hole transport layer 8, the second collector 35 does not need to be able to block electrons coming from the light absorber 4. This means that the second collector 35 can be made of a material that forms an ohmic contact to the light absorber 4. The second collector 35 can therefore be permeable to light.

At least one of the first collector 32 and the second collector 35 is permeable to light and is configured in a similar way to the first collector 2.

When one of the first collector 32 and the second collector 35 is light-permeable, the other may be impermeable to light. The light-impermeable collector does not need to have empty areas, in which the electrode material does not exist.

### Substrate 31

The substrate 31 can be configured in a similar way to the substrate 1. When the second collector 35 is permeable to light, the substrate 31 can be made of a nontransparent material, such as a metal, a ceramic material, or a resin material with low light permeability.

### Hole Transport Layer 8

The hole transport layer 8 can be composed of materials such as organic compounds and inorganic semiconductors. The hole transport layer 8 can be a stack of layers of such materials and can also be a stack of alternating layers of two materials.

Examples of organic compounds that can be used include phenylamine and triphenylamine derivatives that have a tertiary amine as well as PEDOT compounds, which have the thiophene structure. The molecular weight is not limited, and polymers can also be used. When the hole transport layer 8 is formed of an organic compound, its thickness can be 1 nm or more and 1000 nm or less and can be 100 nm or more and 500 nm or less. The hole transport layer 8 has sufficient ability to transport holes and maintains low resistance when its thickness is in this range.

Examples of suitable inorganic semiconductors include p-type semiconductors such as CuO, Cu₂O, CuSCN, molybdenum oxide, and nickel oxide. When the hole transport layer 8 is formed of an inorganic semiconductor, its thickness can be 1 nm or more and 1000 nm or less and can be 10 nm or more and 50 nm or less. The hole transport layer 8 has sufficient ability to transport holes and maintains low resistance when its thickness is in this range.

The formation of the hole transport layer 8 can be through coating or printing, such as doctor blade coating, bar coating, spray coating, dip coating, spin coating, or screen printing. A film of a mixture may optionally be processed, e.g., pressed or fired. Techniques such as vacuum deposition can also be used to prepare the hole transport layer 8 if the material is an organic low-molecular-weight compound or inorganic semiconductor.

The hole transport layer 8 may contain a supporting electrolyte and a solvent.

The supporting electrolyte can be, for example, an ammonium salt or an alkali metal salt. Examples of ammonium salts that can be used include tetrabutylammonium perchlorate, tetraethylammonium hexafluorophosphate, imidazolium salts, and pyridinium salts. Examples of suitable alkali metal salts include lithium perchlorate and potassium tetrafluoroborate.

The solvent in the hole transport layer 8 may be highly ion conductive and can be an aqueous or organic solvent. The use of an organic solvent in the hole transport layer 8 leads to higher stability of the solute. Examples of organic solvents that can be used include carbonate compounds, ester compounds, ether compounds, heterocyclic compounds, nitrile compounds, and aprotic polar compounds.

Examples of suitable carbonate compounds include dimethyl carbonate, diethyl carbonate, methyl ethyl carbonate, ethylene carbonate, and propylene carbonate. Examples of suitable ester compounds include methyl acetate, methyl propionate, and γ-butyrolactone. Examples of suitable ether compounds include diethyl ether, 1,2-dimethoxyethane, 1,3-dioxolane, tetrahydrofuran, and 2-methyl-tetrahydrofuran. Examples of suitable heterocyclic compounds include 3-methyl-2-oxazolidinone and 2-methylpyrrolidone. Examples of suitable nitrile compounds include acetonitrile, methoxyacetonitrile, and propionitrile. Examples of suitable aprotic polar compounds include sulfolane, dimethylsulfoxide, and dimethylformamide.

These solvents can be used alone or in a mixture of two or more. The solvent in the hole transport layer 8 can be a carbonate compound such as ethylene carbonate or propylene carbonate, y-butyrolactone, a heterocyclic compound such as 3-methyl-2-oxazolidinone or 2-methylpyrrolidone, or a nitrile compound such as acetonitrile, methoxyacetonitrile, propionitrile, 3-methoxypropionitrile, or valeronitrile.

The solvent can also be an ionic liquid, alone or mixed with any other solvent. Ionic liquids are of low volatility and highly flame-retardant.

Examples of ionic liquids that can be used include imidazolium-based ionic liquids such as 1-ethyl-3-methylimidazolium tetracyanoborate, pyridine-based, alicyclic amine-based, aliphatic amine-based, and azonium amine-based ionic liquids.

### Fourth Embodiment

A solar cell 400 according to this embodiment differs from the solar cell 300 according to the third embodiment in that it has a porous layer 7. In other words, the solar cell 400 is different from the solar cell 200 according to the second embodiment in that it has a hole transport layer 8.

The following describes the solar cell 400. Any component equivalent in terms of function and configuration to one described in the context of the solar cell 200 or 300 is referenced by the same numeral as for the solar cell 200 or 300 without repeating the description.

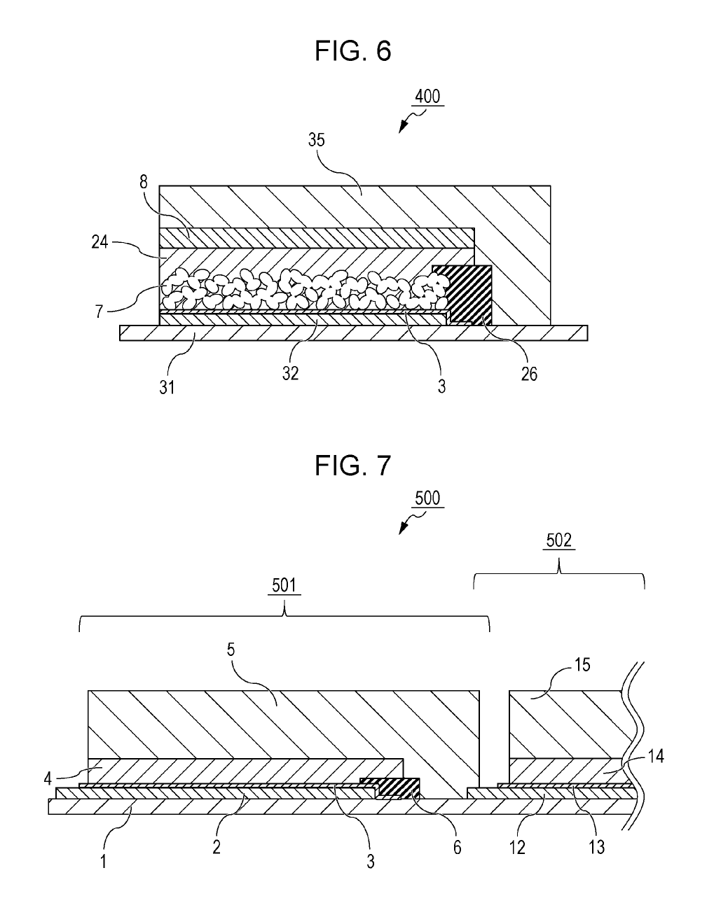

The solar cell 400 according to this embodiment has, as illustrated in FIG. 6, a substrate 31, a first collector 32, an electron transport layer 3, a dielectric 26, a porous layer 7, a light absorber 24, a hole transport layer 8, and a second collector 35.

The solar cell 400 operates in a similar way to the solar cell 300. The advantages this embodiment offers are similar to those of the second and third embodiments.

The fabrication of the solar cell 400 according to this embodiment is similar to that of the solar cells 200 and 300.

### Fifth Embodiment

A solar cell module 500 according to this embodiment has, as illustrated in FIG. 7, solar cells 501 and 502. The solar cell 502 is configured in the same way as the solar cell 501, although only partially illustrated in FIG. 7. The configuration of the solar cells 501 and 502 is basically the same as that of the solar cell 100 according to the first embodiment.

The solar cell 501 has, as illustrated in FIG. 7, a substrate 1, a first collector 2, an electron transport layer 3, a first dielectric 6, a first light absorber 4, and a second collector 5.

The solar cell 502, sharing the substrate 1 with the solar cell 501, has a third collector 12, a second electron transport layer 13, a second dielectric (not illustrated), a second light absorber 14, and a fourth collector 15.

The second collector 5 of the solar cell 501 is in contact with a portion of the third collector 12 of the solar cell 502.

The following describes the key operations and advantages of the solar cell module 500 according to this embodiment.

The operations and advantages of the solar cells 501 and 502 are similar to those of the solar cell 100 according to the first embodiment.

The second collector 5 of the solar cell 501 is in contact with the third collector 12 of the solar cell 502. The solar cells 501 and 502 are therefore connected in series. As a result, the user can take out electric current using the first collector 2 of the solar cell 501 and the fourth collector 15 of the solar cell 502 as an anode and a cathode, respectively.

The following provides further details of the individual components of the solar cell module 500, excluding those the solar cell 100 also has.

The third collector 12, the second electron transport layer 13, the second light absorber 14, the fourth collector 15, and the second dielectric of the solar cell 502 can be configured in a similar way to the first collector 2, the electron transport layer 3, the light absorber 4, the second collector 5, and the dielectric 6, respectively.

The second electron transport layer 13, the second light absorber 14, and the fourth collector 15 are spaced from the second collector 5. This is because contact of the second electron transport layer 13, the second light absorber 14, and/or the fourth collector 15 to the second collector 5 would cause leakage current by short-circuiting the solar cells 501 and 502. The second light absorber 14 may leave the second electron transport layer 13 partially exposed. In such a configuration, the second electron transport layer 13 isolates the second light absorber 14 from the third collector 12, making leakage current less likely.

The solar cells 501 and 502 may be configured in a similar way to any of the solar cells 200, 300, and 400. Furthermore, the solar cells 501 and 502 do not need to share the same configuration. The solar cell module 500 may have three or more solar cells.

The fabrication of the solar cell module 500 according to this embodiment is similar to that of the solar cell 100.

### EXAMPLES

The following describes the present disclosure in further detail by providing some examples. Solar cells of Examples 1 and 2 and Comparative Examples 1 to 4 were fabricated and evaluated for their characteristics. Table 1 summarizes the results.

### Example 1

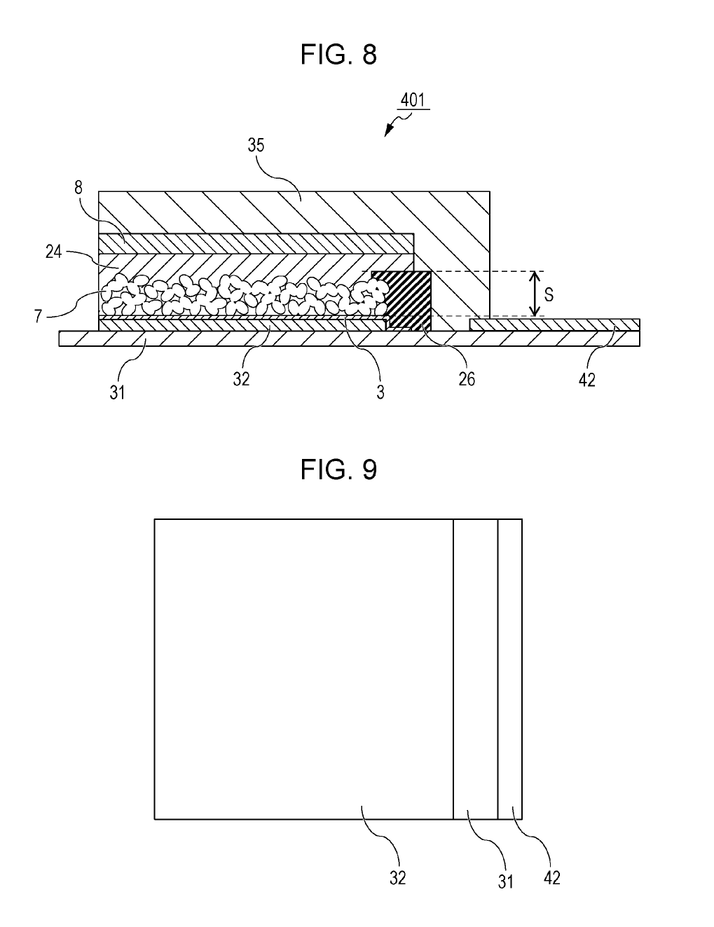

A solar cell having the same structure as the solar cell 401 in FIG. 8 was fabricated. The solar cell 401 has a fifth collector 42 in addition to the structure of the solar cell 400. The components used were as follows.

Substrate 31: A glass substrate (0.7 mm thick)
First collector 32: A fluorine-doped SnO₂ layer (a surface resistance of 10 Ω/sq.)
Fifth collector 42: A fluorine-doped SnO₂ layer (a surface resistance of 10 Ω/sq.)
Electron transport layer 3: Titanium oxide (30 nm thick)
Porous layer 7: Porous titanium oxide (200 nm thick)
Light absorber 24: CH₃NH₃PbI₃ (300 nm thick)
Hole transport layer 8: Spiro-OMeTAD (Merck) (300 nm thick)
Dielectric 26: Polystyrene
Second collector 35: Silver (10 μm thick)

The fabrication of the solar cell of Example 1 was as follows.

A 0.7 mm thick conductive glass substrate (Nippon Sheet Glass) was prepared having a fluorine-doped SnO₂ layer on its principal surface. This glass substrate was used as a substrate 31.

The fluorine-doped SnO₂ layer on the substrate 31 was partially removed using laser treatment, shaping it into a first collector 32 and a fifth collector 42 having the pattern illustrated in FIG. 9.

An approximately 30 nm thick titanium oxide layer as an electron transport layer 3 was formed on the first collector 32 using sputtering.

A high-purity titanium oxide powder having an average primary particle diameter of 20 nm was dispersed in ethyl cellulose, and the resulting titanium oxide paste was spread over the electron transport layer 3 and dried. The dry coating was fired in air at 500° C. for 30 minutes to form a 0.2 μm thick porous titanium oxide layer as a porous layer 7.

A 7 mg/ml solution of polystyrene in chloroform was applied to a portion of the electron transport layer 3 and an area of the substrate 31 not covered by the first collector. The coating was dried to form a dielectric 26.

A solution containing 1 mol/L of PbI₂ and 1 mol/L of methylammonium iodide in dimethylsulfoxide (DMSO) was applied to the porous layer 7 using spin coating. Subsequent heating on a hot plate at 130° C. yielded a layer of perovskite structured CH₃NH₃PbI₃ as a light absorber 24.

A solution containing the following materials in chlorobenzene was applied to the light absorber 24 using spin coating to form a hole transport layer 8: 60 mmol/L of Spiro-OMeTAD, 30 mmol/L of lithium bis(trifluorosulfonyl)imide (LiTFSI), 200 mmol/L of tert-butylpyridine (tBP), and 1.2 mmol/L of a Co complex (FK 209; Dyesol Limited).

Lastly, a silver paste was spread over the hole transport layer 8 and the dielectric 26, reaching the fifth collector 42, to form a silver layer as a second collector 35.

### Example 2 and Comparative Examples 1 to 3

The fabrication of the solar cell of Example 1 was repeated, but the concentration of the polystyrene solution used to form the dielectric 26 was changed to 13 mg/ml in Example 2, 16 mg/ml in Comparative Example 1, 26 mg/ml in Comparative Example 2, and 67 mg/ml in Comparative Example 3. The amount of polystyrene solution used in Example 2 and Comparative Examples 1 to 3 was the same as that in the fabrication of the solar cell of Example 1.

### Comparative Example 4

The fabrication of the solar cell of Example 2 was repeated, but with a gap of 500 μm between the light absorber 24 and the dielectric 26 to avoid contact.

### Evaluation

### Measurement of Step Height

The step height S in FIG. 8 was measured using a probe profilometer. The step height S corresponds to the difference between the height, from the principal surface of the substrate 31, of the top of the dielectric 26 in the region where it covers a portion of the electron transport layer 3 and the combined thickness of the first collector 32 and the electron transport layer 3 measured from the principal surface of the substrate 31 in the cross-section of the solar cell 401 illustrated in FIG. 8. The results are summarized in Table 1.

### Measurement of Leakage Current

A voltage of +0.1 V was applied across the first collector 32 and the fifth collector 42, and the current was measured. The results are summarized in Table 1.

TABLE 1

| | | | Gap | | |
|---|---|---|---|---|---|
| | | | between | | |
| | | | dielectric | | |
| | Concentration | Step | and | | |
| | of polystyrene | height | light | Leakage | |
| | solution | S | absorber | current | |
| Example 1 | 7 mg/ml | 73 nm | — | 1 | μA |
| Example 2 | 13 mg/ml | 160 nm | — | 1.1 | μA |
| Comparative | 16 mg/ml | 210 nm | — | 1300 | μA |
| Example 1 | | | | | |
| Comparative | 26 mg/ml | 350 nm | — | 1240 | μA |
| Example 2 | | | | | |
| Comparative | 67 mg/ml | 1100 nm | — | 1410 | μA |
| Example 3 | | | | | |
| Comparative | 13 mg/ml | 160 nm | 500 μm | 1070 | μA |
| Example 4 | | | | | |

As can be seen from the results in Table 1, when Example 2 and Comparative Example 4 are compared, the leakage current is smaller in Example 2 than in Comparative Example 4 despite the same step height S of 160 nm. This indicates that leakage current is less likely when the light absorber 24 is partially on the dielectric 26.

Furthermore, the leakage current values in Examples 1 and 2 are smaller than those in Comparative Examples 1 to 3. This indicates that leakage current is less likely when the step height S is 200 nm or less.

What is claimed is:

1. A solar cell comprising:
a substrate having a principal surface;
a first collector on the principal surface;
a dielectric covering a portion of the principal surface and a first portion of the first collector;
a light absorber covering at least a second portion of the first collector and a portion of the dielectric and containing a perovskite compound represented by a compositional formula of ABX₃, where A is a site for one or more monovalent cations, B is a site for one or more divalent cations, and X is a site for one or more halide anions; and
a second collector on the light absorber and the dielectric, the second collector insulated from the first collector by the dielectric, wherein
in a cross-section perpendicular to the principal surface,
a difference between a height, from the principal surface, of a top of the dielectric in a region where the dielectric covers the first portion of the first collector and
a height, from the principal surface, of a bottom of the light absorber in a region where the light absorber covers the at least the second portion of the first collector and does not cover the dielectric is 200 nm or less.

2. The solar cell according to claim 1, further comprising an electron transport layer between the first collector and the light absorber, the electron transport layer containing a semiconductor, wherein
the dielectric covers a portion of the electron transport layer.

3. The solar cell according to claim 2, further comprising a porous layer in the light absorber, the porous layer positioned in contact with the electron transport layer and including a porous medium.

4. The solar cell according to claim 1, further comprising a hole transport layer between the light absorber and the second collector.

5. The solar cell according to claim 2, wherein the semiconductor is titanium oxide.

6. The solar cell according to claim 1, wherein the second collector contains carbon.

7. The solar cell according to claim 1, wherein the one or more monovalent cations include at least one selected from the group consisting of a methylammonium cation and a formamidinium cation.

8. The solar cell according to claim 1, wherein the one or more divalent cations include at least one selected from the group consisting of Pb²⁺, Ge²⁺, and Sn²⁺.

9. A solar cell comprising:
a substrate having a principal surface;
a first collector on the principal surface;
a dielectric covering a portion of the principal surface and a first portion of the first collector;
a light absorber covering at least a second portion of the first collector and a portion of the dielectric and containing a perovskite compound represented by a compositional formula of ABX₃, where A is a site for one or more monovalent cations, B is a site for one or more divalent cations, and X is a site for one or more halide anions; and
a second collector on the light absorber and the dielectric, the second collector insulated from the first collector by the dielectric, wherein
in a cross-section perpendicular to the principal surface,
a ratio of a difference between a height, from the principal surface, of a top of the dielectric in a region where the dielectric covers the first portion of the first collector and
a height, from the principal surface, of a bottom of the light absorber in a region where the light absorber covers the at least the second portion of the first collector and does not cover the dielectric to a thickness of the light absorber is 0.67 or less.

10. A solar cell module comprising:
a first solar cell including:
a substrate having a principal surface;
a first collector on the principal surface;
a first dielectric covering a first portion of the principal surface and a first portion of the first collector;
a first light absorber covering at least a second portion of the first collector and a portion of the first dielectric and containing a perovskite compound represented by a compositional formula of ABX₃, where A is a site for one or more monovalent cations, B is a site for one or more divalent cations, and X is a site for one or more halide anions; and
a second collector on the first light absorber and the first dielectric, the second collector insulated from the first collector by the first dielectric, wherein
in a cross-section perpendicular to the principal surface,
a difference between a height, from the principal surface, of a top of the first dielectric in a region where the first dielectric covers the first portion of the first collector and
a height, from the principal surface, of a bottom of the first light absorber in a region where the first light absorber covers the at least the second portion of the first collector and does not cover the first dielectric is 200 nm or less; and
a second solar cell including:
a third collector on the principal surface, the third collector adjacent to the first collector;
a second dielectric covering a second portion of the principal surface and a first portion of the third collector;
a second light absorber covering at least a second portion of the third collector and a portion of the second dielectric and containing the perovskite compound; and
a fourth collector on the second light absorber and the second dielectric, the fourth collector insulated from the third collector by the second dielectric, wherein
in a cross-section perpendicular to the principal surface,
a difference between a height, from the principal surface, of a top of the second dielectric in a region where the second dielectric covers the first portion of the third collector and
a height, from the principal surface, of a bottom of the second light absorber in a region where the second light absorber covers the at least the second portion of the third collector and does not cover the second dielectric is 200 nm or less, wherein
the second collector is in contact with a portion of the third collector.
